(19) United States
(12) Patent Application Publication
(10) Pub. No.: US 2009/0057734 A1
(43) Pub. Date: Mar. 5, 2009

(54) IMAGE SENSOR

(75) Inventors: Kaori Misawa, Kaizu-shi (JP); Ryu Shimizu, Mizuho-shi (JP); Mamoru Arimoto, Ogaki-shi (JP); Hayato Nakashima, Anpachi-gun (JP)

Correspondence Address: DITTHAVONG MORI & STEINER, P.C., 918 Prince St., Alexandria, VA, 22314, US

(73) Assignee: Sanyo Electric Co., Ltd., Moriguchi-shi (JP)

(21) Appl. No.: 12/201,995

(22) Filed: Aug. 29, 2008

(30) Foreign Application Priority Data
Aug. 31, 2007 (JP) 2007-225249

(51) Int. Cl. H01L 27/146

(52) U.S. Cl. 257/292; 257/E27.133

(57) ABSTRACT

An image sensor includes a photoelectric conversion portion generating signal charges, a first electrode for forming an electric field transferring the signal charges generated by the photoelectric conversion portion, formed to be adjacent to the photoelectric conversion portion; and a second electrode for forming an electric field transferring the signal charges, provided on a side opposite to the photoelectric conversion portion with respect to the first electrode and formed to partially extend on the first electrode.

### CROSS-REFERENCE TO RELATED APPLICATIONS

The priority application number JP2007-225249, Image Sensor, Aug. 30, 2007, Kaori Misawa, Ryu Shimizu, Mamoru Arimoto, Hayato Nakashima, upon which this patent application is based is hereby incorporated by reference.

### BACKGROUND OF THE INVENTION

1. Field of the Invention

The present invention relates to an image sensor, and more particularly, it relates to an image sensor comprising an electrode for forming an electric field storing signal charges.

2. Description of the Background Art

A CMOS (complementary metal oxide semiconductor) image sensor comprising a photoelectric conversion portion generating electrons (signal charges) is known in general.

Japanese Patent Laying-Open No. 2004-165467 discloses a CMOS image sensor comprising a photodiode (photoelectric conversion portion) and an electronic shutter read electrode removing charges in the photodiode, a signal read electrode reading the charges in the photodiode, a signal storage electrode storing the read charges and an output gate outputting the stored charges. In this CMOS image sensor described in Japanese Patent Laying-Open No. 2004-165467, the photodiode has a first side surface connected to the electronic shutter read electrode and a second side surface connected to the signal read electrode, the signal storage electrode and the output gate successively from a side of the photodiode in plan view.

### SUMMARY OF THE INVENTION

An image sensor according to an aspect of the present invention comprises a photoelectric conversion portion generating signal charges, a first electrode for forming an electric field transferring the signal charges generated by the photoelectric conversion portion, formed to be adjacent to the photoelectric conversion portion, and a second electrode for forming an electric field transferring the signal charges, provided on a side opposite to the photoelectric conversion portion with respect to the first electrode and formed to partially extend on the first electrode.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view showing an overall structure of a CMOS image sensor according to a first embodiment of the present invention;

FIG. 2 is a sectional view in the CMOS image sensor according to the first embodiment;

FIGS. 3 and 4 are sectional views showing the structure of the CMOS image sensor according to the first embodiment;

FIG. 5 is a plan view showing pixels of the CMOS image sensor according to the first embodiment;

FIG. 6 is a circuit diagram showing a circuit structure of the CMOS image sensor according to the first embodiment;

FIG. 7 is a potential diagram for illustrating an electron transferring operation of the CMOS image sensor according to the first embodiment;

FIG. 8 is a signal waveform diagram for illustrating the electron transferring operation of the CMOS image sensor according to the first embodiment;

FIG. 9 is a potential diagram for illustrating an electron multiplying operation of the CMOS image sensor according to the first embodiment;

FIG. 10 is a signal waveform diagram for illustrating the electron multiplying operation of the CMOS image sensor according to the first embodiment;

FIG. 11 is a plan view showing an overall structure of a CMOS image sensor according to a second embodiment;

FIGS. 12, 13 and 14 are sectional views showing the structure of the CMOS image sensor according to the second embodiment;

FIG. 15 is a plan view showing pixels of the CMOS image sensor according to the second embodiment;

FIG. 16 is a circuit diagram showing a circuit structure of the CMOS image sensor according to the second embodiment;

FIG. 17 is a potential diagram for illustrating an electron transferring operation of the CMOS image sensor according to the second embodiment;

FIG. 18 is a signal waveform diagram for illustrating the electron transferring operation of the CMOS image sensor according to the second embodiment;

FIG. 19 is a diagram for illustrating a modification according to the second embodiment; and

FIGS. 20 and 21 are diagrams for illustrating a modification according to each of the first and second embodiments.

### DESCRIPTION OF THE PREFERRED EMBODIMENTS

Embodiments of the present invention will be hereinafter described with reference to the drawings.

### First Embodiment

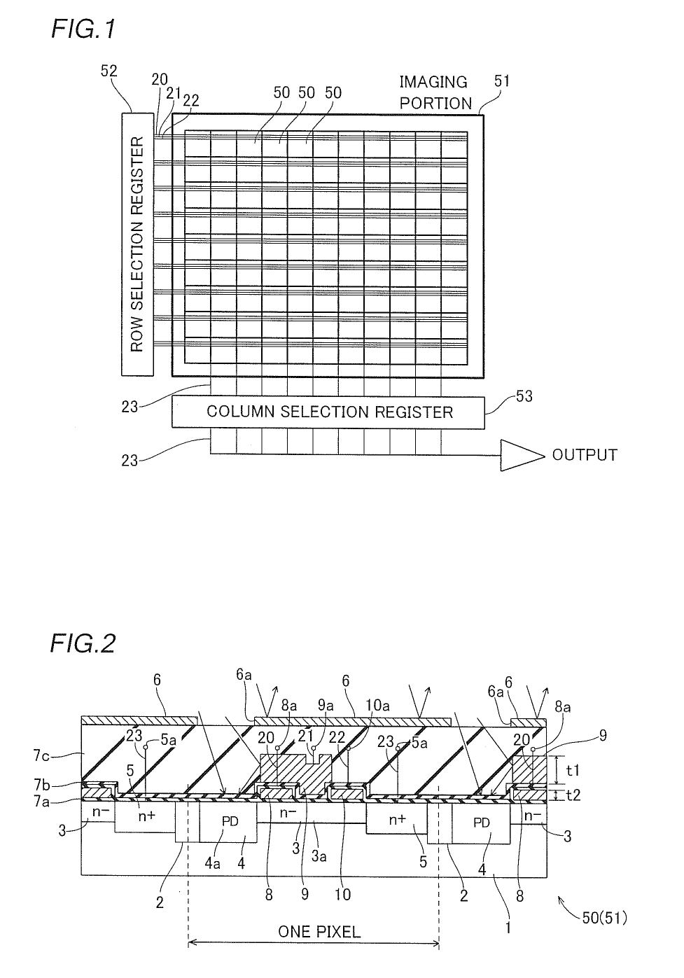

A CMOS image sensor according to a first embodiment comprises an imaging portion 51 including a plurality of pixels 50 arranged in the form of a matrix, a row selection register 52 and a column selection register 53, as shown in FIG. 1.

As to a sectional structure of the pixels 50 of the CMOS image sensor according to the first embodiment, element isolation regions 2 for isolating the pixels 50 from each other are formed on a surface of a p-type silicon substrate 1, as shown in FIGS. 2 to 4. On a surface portion of the p-type silicon substrate 1 provided with each pixel 50 enclosed with the corresponding element isolation regions 2, a photodiode (PD) portion 4 and a floating diffusion (FD) region 5 made of an n⁺-type impurity region are formed at a prescribed interval, to hold a transfer channel 3 made of an n⁻-type impurity region therebetween. A light shielding film 6 for inhibiting light from incidence upon the pixels is formed on upper surfaces of the pixels 50 of the imaging portion 51. In the light shielding film 6, an incident hole 6a for guiding light from outside to the PD portion 4 is formed on a region located above the PD portion 4 of each pixel 50. The light shielding film 6 is made of Al (aluminum), for example. The PD portion 4 and the FD region 5 are examples of the “photoelectric conversion portion” and the “voltage conversion portion” in the present invention respectively.

The PD portion 4 has a function of generating electrons in response to the quantity of incident light and storing the generated electrons. The PD portion 4 is formed to be adjacent to the corresponding element isolation region 2 as well as to the transfer channel 3. The FD region 5 has an impurity concentration (n+) higher than the impurity concentration (n−) of the transfer channel 3. The FD region 5 has a function of holding a charge signal formed by transferred electrons and converting the charge signal to a voltage. The FD region 5 is formed to be adjacent to the corresponding element isolation region 2 as well as to the transfer channel 3. Thus, the FD region 5 is opposed to the PD portion 4 through the transfer channel 3.

A first insulating film 7a made of SiO₂ is formed on upper surfaces of the transfer channel 3, the PD portion 4 and the FD region 5. On the first insulating film 7a, a transfer gate electrode 8, a multiplier gate electrode 9 and a read gate electrode 10 are formed in this order from a side of the PD portion 4 toward a side of the FD region 5. The transfer gate electrode 8, the multiplier gate electrode 9 and the read gate electrode 10 are formed on the first insulating film 7a and side surfaces and upper surfaces of the transfer gate electrode 8 and the read gate electrode 10 are covered with the first insulating film 7a. A second insulating film 7b made of SiN is formed on the first insulating film 7a. An interlayer dielectric film 7c made of SiO₂ or SiN is formed between the second insulating film 7b and the light shielding film 6 so as to cover the second insulating film 7b and the gate electrodes. The multiplier gate electrode 9 is made of a polysilicon film and formed on the second insulating film 7b. The second insulating film 7b is an example of the “anti-reflection film” in the present invention and the interlayer dielectric film 7c is an example of the “insulating film” in the present invention. The transfer gate electrode 8, the multiplier gate electrode 9 and the read gate electrode 10 are examples of the “first electrode”, the “second electrode” and the “third electrode” in the present invention respectively.

The transfer gate electrode 8 is formed between the PD portion 4 and the multiplier gate electrode 9. The read gate electrode 10 is formed between the multiplier gate electrode 9 and the FD region 5. The read gate electrode 10 is so formed as to be adjacent to the FD region 5.

According to the first embodiment, the multiplier gate electrode 9 is formed to partially extend on the upper surfaces of the transfer gate electrode 8 through the first insulating film 7a and the second insulating film 7b so that the multiplier gate electrode 9 is formed to be adjacent to the PD portion 4. According to the first embodiment, the thickness (t1 in FIG. 2) of the multiplier gate electrode 9 is larger than each of the thicknesses (t2 in FIG. 2) of the electrodes other than the multiplier gate electrode 9. The multiplier gate electrode 9 (refractive index: about 3.42) made of the polysilicon film has a refractive index higher than that of the interlayer dielectric film 7c (the refractive index of the film made of a SiO₂ film: about 1.46 or the refractive index of the film made of SiN film: about 2.00) formed on the first insulating film 7a and the second insulating film 7b, and hence light passing through the incident hole 6a of the light shielding film 6 is reflected by a side wall of the multiplier gate electrode 9 to be guided to the PD portion 4.

As shown in FIG. 5, wiring layers 20, 21 and 22 supplying clock signals φ1, φ2 and φ3 for voltage control are electrically connected to the transfer gate electrode 8, the multiplier gate electrode 9 and the read gate electrode 10 through contact portions 8a, 9a and 10a respectively. The wiring layers 20, 21 and 22 are formed every row, and electrically connected to the transfer gate electrodes 8, the multiplier gate electrodes 9 and the read gate electrodes 10 of the plurality of pixels 50 forming each row respectively. A signal line 23 for extracting a signal through a contact portion 5a is electrically connected to the FD region 5. This signal line 23 is formed every column, and electrically connected to the FD regions 5 of the plurality of pixels 50 forming each row.

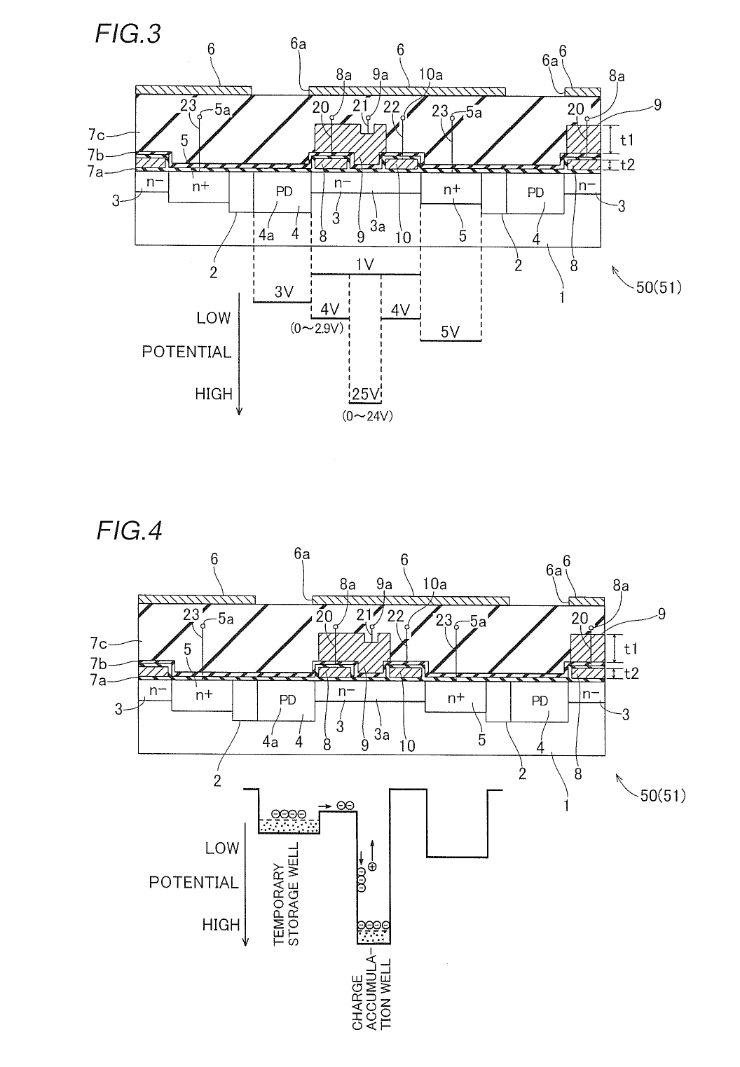

When ON-state (high-level) clock signals φ1 and φ3 are supplied to the transfer gate electrode 8 and the read gate electrode 10 through the wiring layers 20 and 22 respectively, voltages of about 2.9 V are applied to the transfer gate electrode 8 and the read gate electrode 10, as shown in FIG. 3. Thus, portions of the transfer channel 3 located under the transfer gate electrode 8 and the read gate electrode 10 respectively are controlled to potentials of about 4 V when the ON-state (high-level) clock signals φ1 and φ3 are supplied to the transfer gate electrode 8 and the read gate electrode 10 respectively.

When an ON-state (high-level) clock signal φ2 is supplied to the multiplier gate electrode 9 through the wiring layer 21, a voltage of about 24 V is applied to the multiplier gate electrode 9. Thus, the portion of the transfer channel 3 located under the multiplier gate electrode 9 is controlled to a high potential of about 25 V when the ON-state (high-level) clock signal φ2 is supplied to the multiplier gate electrode 9.

When OFF-state (low-level) clock signals φ1, φ2 and φ3 are supplied to the transfer gate electrode 8, the multiplier gate electrode 9 and the read gate electrode 10 respectively, voltages of about 0 V are applied to the transfer gate electrode 8, the multiplier gate electrode 9 and the read gate electrode 10. Thus, the portions of the transfer channel 3 located under the transfer gate electrode 8, the multiplier gate electrode 9 and the read gate electrode 10 respectively are controlled to potentials of about 1 V. The FD region 5 is controlled to a potential of about 5 V.

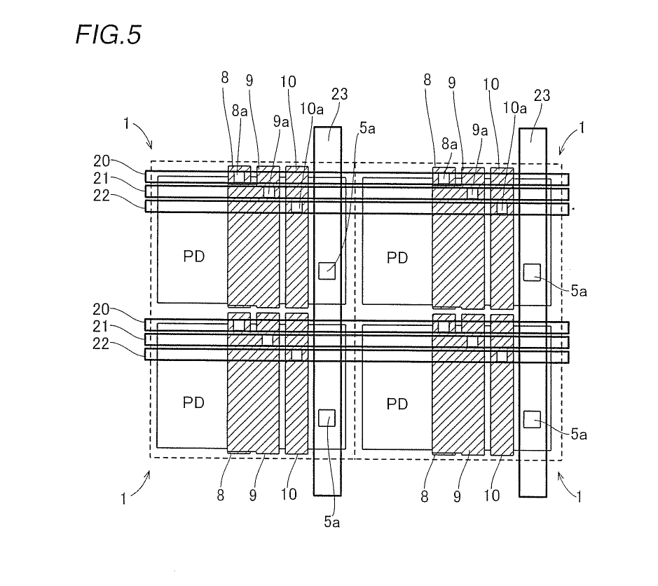

According to the first embodiment, the PD portion 4 has a function of generating electrons by photoelectric conversion and also has a function as an electron storage portion 4a storing the generated electrons, as shown in FIG. 4. The transfer gate electrode 8 has a function of transferring electrons stored in the electron storage portion 4a of the PD portion 4 to the electron multiplying portion 3a located on the portion of the transfer channel 3 located under the multiplier gate electrode 9 through the portion of the transfer channel 3 located under the transfer gate electrode 8 by supplying the ON-state signal.

When the electrons stored in the PD portion 4 are multiplied, a high electric field is applied to the electron multiplying portion 3a located on the portion of the transfer channel 3 located under the multiplier gate electrode 9 by supplying the ON-state signal to the multiplier gate electrode 9. Then the speed of the electrons transferred from the PD portion 4 is increased by the high electric field generated in the electron multiplying portion 3a and the electrons transferred from the PD portion 4 are multiplied by impact ionization with atoms in the impurity region. The impact ionization of the electrons is caused in the vicinity of the boundary between the portion of the transfer channel 3 located under the multiplier gate electrode 9 (electron multiplying portion 3a) and the portion of the transfer channel 3 located under the transfer gate electrode 8. The electron multiplying portion 3a is an example of the “charges increasing portion” in the present invention.

The portion of the transfer channel 3 located under the transfer gate electrode 8 has a function of transferring the electrons stored in the electron storage portion 4a of the PD portion 4 to the electron multiplying portion 3a located on the portion of the transfer channel 3 located under the multiplier gate electrode 9 when the ON-state (high-level) signal is supplied to the transfer gate electrode 8. Additionally, the portion of the transfer channel 3 located under the transfer gate electrode 8 has a function of dividing the electron storage portion 4a of the PD portion and the portion of the transfer channel 3 located under the multiplier gate electrode 9 (electron multiplying portion 3a) from each other when the OFF-state (low-level) signal is supplied to the transfer gate electrode 8.

The portion of the transfer channel 3 located under the read gate electrode 10 has a function of transferring the electrons stored in the portion of the transfer channel 3 located under the multiplier gate electrode 9 (electron multiplying portion 3a) to the FD region 5 when the ON-state (high-level) signal is supplied to the read gate electrode 10, and a function of dividing the portion of the transfer channel 3 located under the multiplier gate electrode 9 (electron multiplying portion 3a) and the FD region 5 from each other when the OFF-state (low-level) signal is supplied to the read gate electrode 10.

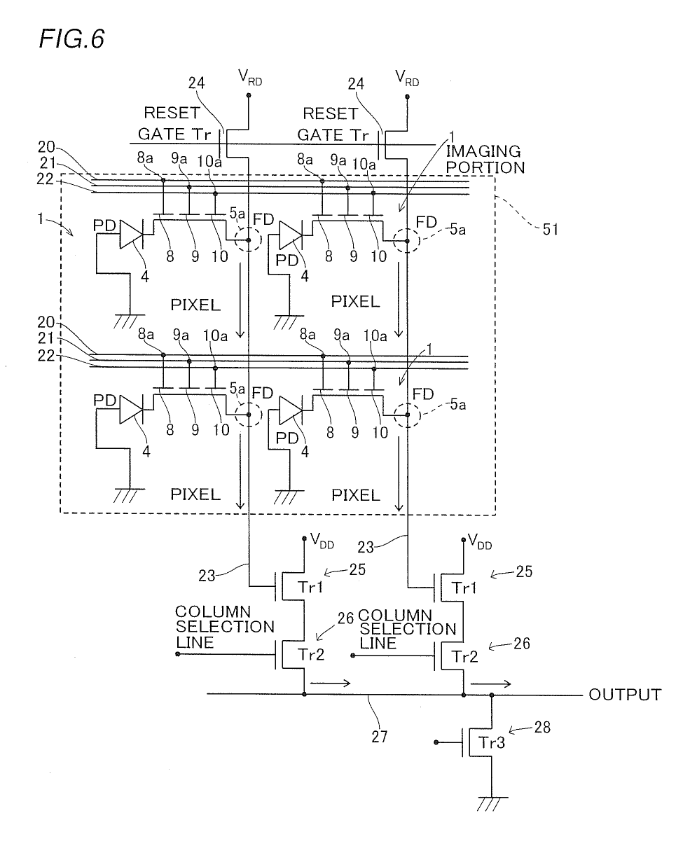

As shown in FIG. 6, a source of a reset gate transistor 24 is connected to a first end of the signal line 23 corresponding to each column. A reset signal is supplied to a gate of the reset gate transistor 24, while a reset voltage V_{RD} (about 5 V) is applied to a drain thereof. Thus, the reset gate transistor 24 has a function of resetting the signal line 23 to the reset voltage V_{RD} (about 5 V) after data is read from each pixel 50 while holding the FD region 5 in an electrically floating state when the data is read from the pixel 50.

A second end of the signal line 23 corresponding to each column is connected to a gate of a voltage conversion transistor 25 (Tr1). A source of the voltage conversion transistor 25 is connected to a drain of a selection transistor 26 (Tr2), and a power supply voltage V_{DD} is supplied to a drain thereof. A column selection line is connected to a gate of the selection transistor 26, and an output line 27 is connected to a source thereof. A drain of a transistor 28 (Tr3) is connected to the output line 27. A source of the transistor 28 is grounded, and a prescribed voltage for driving the transistor 28 as a constant current source is applied to a gate thereof. The voltage conversion transistor 25 corresponding to each column and the transistor 28 constitute a source follower circuit.

A read operation of the CMOS image sensor according to the first embodiment will be now described with reference to FIGS. 5 and 6. First, a high-level signal is supplied to the wiring layer 22 of a prescribed row to bring the read gate electrodes 10 into an ON state. Thus, electrons generated by the PD portions 4 in the pixels 50 forming the prescribed row of the imaging portion 51 are read on the signal lines 23. In this state, the transistors 26 are in an ON-state while the transistors 27 are in an OFF-state, and hence no current flows in the source follower circuits constituted of the transistors 26 and the transistors 28. From this state, high-level signals are successively supplied to the column selection lines, to successively bring the transistors 27 of the pixels 50 forming each prescribed row of the imaging portion 51 into ON states. Thus, a current successively flows through the transistor 26 and the transistor 27 corresponding to each column and the transistor 28, whereby a signal is output every pixel 50. After all outputs are completed, the reset gate transistors 24 are brought into an ON state, thereby resetting the potentials of the signal line 23. The CMOS image sensor according to the first embodiment reads data by repeating this operation.

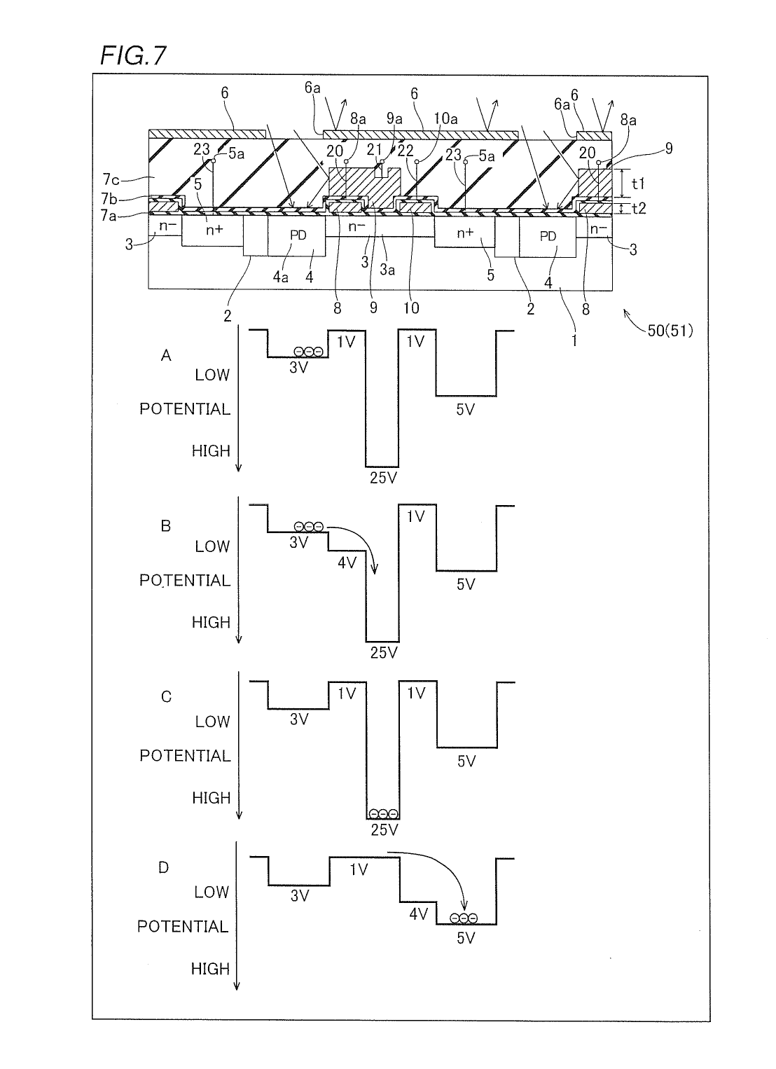

An electron transferring operation and an electron multiplying operation of the CMOS image sensor according to the first embodiment will be now described with reference to FIGS. 7 to 10.

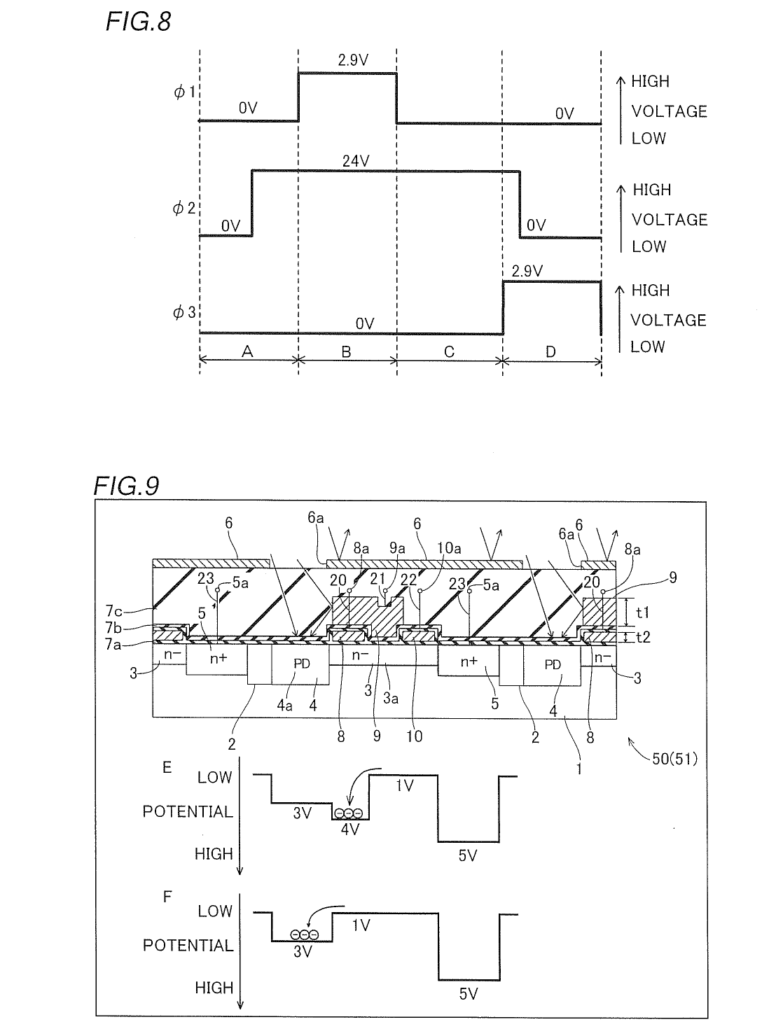

As shown in FIG. 7, when light is incident upon each PD portion 4, the electrons are generated in the PD portion 4 by photoelectric conversion. In a period A shown in FIGS. 7 and 8, a voltage of about 24 V is applied to the multiplier gate electrode 9. Thus, the potential of the portion of the transfer channel 3 located under the multiplier gate electrode 9 is controlled to a high potential of about 25 V (in an ON state). In a period B, a voltage of about 2.9 V is applied to the transfer gate electrode 8 in the state where the portion of the transfer channel 3 located under the multiplier gate electrode 9 is maintained in an ON-state. Thus, electrons stored in the electron storage portion 4a (about 3 V) of the PD portion 4 are transferred to the portion of the transfer channel 3 located under the multiplier gate electrode 9 (electron multiplying portion 3a) having higher potential (about 25 V) through the portion of the transfer channel 3 located under the transfer gate electrode 8 (about 4V). Then electrons are multiplied on the boundary between the portion of the transfer channel 3 located under the transfer gate electrode 8 and the portion of the transfer channel 3 located under the multiplier gate electrode 9 by impact ionization.

In a period C, a voltage of about 0 is applied to the transfer gate electrode 8 to control the portion of the transfer channel 3 located under the transfer gate electrode 8 to be brought into an OFF-state (about 1 V). Thus, the electrons are held in the portion of the transfer channel 3 located under the multiplier gate electrode 9 (electron multiplying portion 3a). In a period D, a voltage of about 2.9 V is applied to the read gate electrode 10 and a voltage of about 0 V is thereafter applied to the multiplier gate electrode 9 to successively control the portion of the transfer channel 3 located under the read gate electrode 10 to a potential of about 4 V and to control the portion of the transfer channel 3 located under the multiplier gate electrode 9 (electron multiplying portion 3a) to a potential of about 1 V. Thus, the electrons held in the electron multiplying portion 3a are transferred to the FD region 5 (about 5 V) through the portion of the transfer channel 3 located under the read gate electrode 10 (about 4 V) and the electron transferring operation is completed.

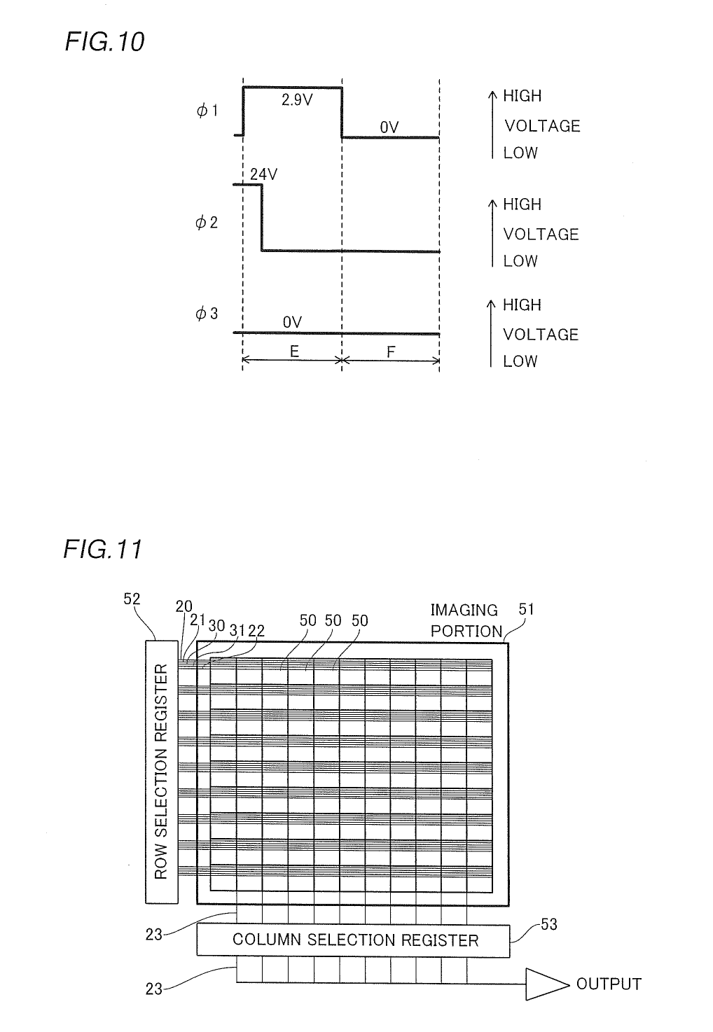

In the electron multiplying operation, the transfer gate electrode 8 is brought into an ON-state and the multiplier gate electrode 9 is thereafter brought into an OFF-state in a period E shown in FIGS. 9 and 10, in the state where the electrons are stored in the portion of the transfer channel 3 located under the multiplier gate electrode 9 (electron multiplying portion 3a) by performing the operations of the periods A to C shown in FIGS. 7 and 8. Thus, the portion of the transfer channel 3 located under the multiplier gate electrode 9 (electron multiplying portion 3a) is controlled to a potential of about 1 V and the portion of the transfer channel 3 located under the transfer gate electrode 8 is controlled to a potential of about 4 V. Thus, the electrons stored in the portion of the transfer channel 3 located under the multiplier gate electrode 9 (electron multiplying portion 3a) are transferred to the portion of the transfer channel 3 located under the transfer gate electrode 8 having a higher potential. In a period F, the transfer gate electrode 8 is brought into an OFF-state to control the portion of the transfer channel 3 located under the transfer gate electrode 8 to a potential of about 1 V. Thus, the electrons are transferred to the electron storage portion 4a of the PD portion 4 having a higher potential. The aforementioned operations in the periods A to C, E and F are controlled to be performed a plurality of times (about 400 times, for example) to multiply the electrons transferred from the PD portion 4 to about 2000 times. The charge signal formed by thus multiplied and stored electrons is read as a voltage signal through the FD region 5 and the signal line 23 by the aforementioned read operation.

According to the first embodiment, as hereinabove described, the multiplier gate electrode 9 is so formed as to be adjacent to the PD portion 4 through the transfer gate electrode 8 and partially extend on the transfer gate electrode 8, whereby light obliquely incident from the incident hole 6a of the light shielding film 6 is reflected by the side surface of the multiplier gate electrode 9 without incidence upon the transfer channel 3. The side surface of the multiplier gate electrode 9 on a side adjacent to the PD portion 4 is aligned substantially along the same line as a side surface of the transfer gate electrode 8 and the multiplier gate electrode 9 is so formed as to partially extend on the transfer gate electrode 8, whereby light advancing toward the transfer gate electrode 8 and the transfer channel 3 can be reliably reflected by the side surface of the multiplier gate electrode 9. Thus, incidence of light upon the transfer channel 3 can be suppressed and hence noise caused on the CMOS image sensor can be suppressed. The light reflected by the side surface of the multiplier gate electrode 9 is incident upon the PD portion 4 and hence a light utilization ratio can be increased. Therefore, the photosensitivity of the CMOS image sensor can be improved.

According to the aforementioned first embodiment, the thickness of the multiplier gate electrode 9 (t1 in FIG. 2) is so formed as to be larger than that of the transfer gate electrode 8 (t2 in FIG. 2), whereby light obliquely incident from the incident hole 6a of the light shielding film 6 can be reliably reflected by the side surface of the multiplier gate electrode 9 and hence incidence of light upon the transfer channel 3 can be reliably suppressed. The thickness of the transfer gate electrode 8 is so formed as to be smaller than that of the multiplier gate electrode 9, tensile stress or compressive stress acting between the PD portion 4 and the transfer gate electrode 8 is reduced due to the smaller thickness and hence formation of crystal defects resulting from stress can be suppressed. Therefore, a dark current resulting from crystal defects can be suppressed.

According to the aforementioned first embodiment, the refractive index (about 3.42) of the multiplier gate electrode 9 made of the polysilicon film is so formed as to be larger than that of the interlayer dielectric film 7c (the refractive index of the SiO₂ film: about 1.46 or the refractive index of the SiN film: about 2.00) formed on the first insulating film 7a made of SiO₂ and the second insulating film 7b made of SiN, and the refractive index of the multiplier gate electrode 9 is about twice the refractive index of the interlayer dielectric film 7c in the CMOS image sensor according to the first embodiment, whereby light obliquely incident from the incident hole 6a formed on the light shielding film 6 can reliably be reflected toward the PD portion 4. The PD portion 4 is covered with the first insulating film 7a made of SiO₂ and the second insulating film 7b made of SiN having lower refractive indexes and hence light can reliably be incident upon the PD portion 4 without reflecting the light. Therefore, condensation efficiency of the PD portion 4 can be improved.

According to the aforementioned first embodiment, the light shielding film 6 is provided on the transfer gate electrode 8, the multiplier gate electrode 9 and the read gate electrode 10, whereby incidence of light upon the portions of the transfer channel 3 located under the transfer gate electrode 8, the multiplier gate electrode 9 and the read gate electrode 10 can be suppressed. Thus, noise resulting from incidence of light upon the electron multiplying portion 3a when electrons are temporarily held in the electron multiplying portion 3a in reading the electrons for example can be suppressed.

### Second Embodiment

Referring to FIGS. 11 to 18, a CMOS image sensor according to a second embodiment of the present invention further comprise a transfer gate electrode 11 for transferring electrons multiplied by an electron multiplying portion 3a under a multiplier gate electrode 9 and a transfer gate electrode 12 for transferring electrons to an FD region 5 through a read gate electrode 10, formed between the transfer gate electrode 11 and the read gate electrode 10 and an electron storage portion 3b is provided on a portion of a transfer channel 3 located under the transfer gate electrode 12 in the structure of the CMOS image sensor according to the aforementioned first embodiment.

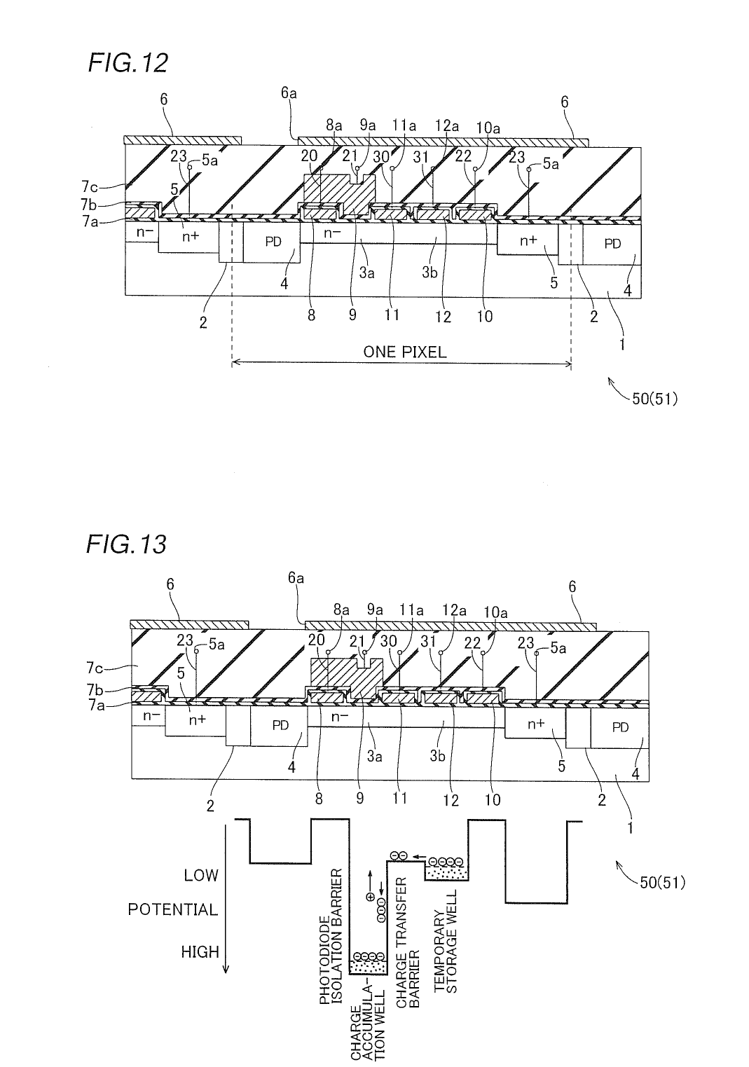

In the CMOS image sensor according to the second embodiment of the present invention, a transfer gate electrode 8, the multiplier gate electrode 9, the transfer gate electrode 11, the transfer gate electrode 12 and the read gate electrode 10 are formed on an upper surface of a first insulating film 7a formed on an upper surface of the transfer channel 3 at prescribed intervals in this order from a side of the PD portion 4 toward a side of the FD region 5 in each of pixels, as shown in FIGS. 12 to 14. Side surfaces and upper surfaces of the transfer gate electrode 8, the transfer gate electrode 11, the transfer gate electrode 12 and the read gate electrode 10 are covered with the first insulating film 7a. A second insulating film 7b is formed on the first insulating film 7a and the multiplier gate electrode 9 is formed on the second insulating film 7b. The multiplier gate electrode 9 is formed to partially extend on an upper surface of the transfer gate electrode 9 through the first insulating film 7a and the second insulating film 7b so as to be adjacent to the PD portion 4, similarly to the aforementioned first embodiment. The transfer gate electrode 11 and the transfer gate electrode 12 are examples of the “fourth electrode” and the “fifth electrode” in the present invention respectively.

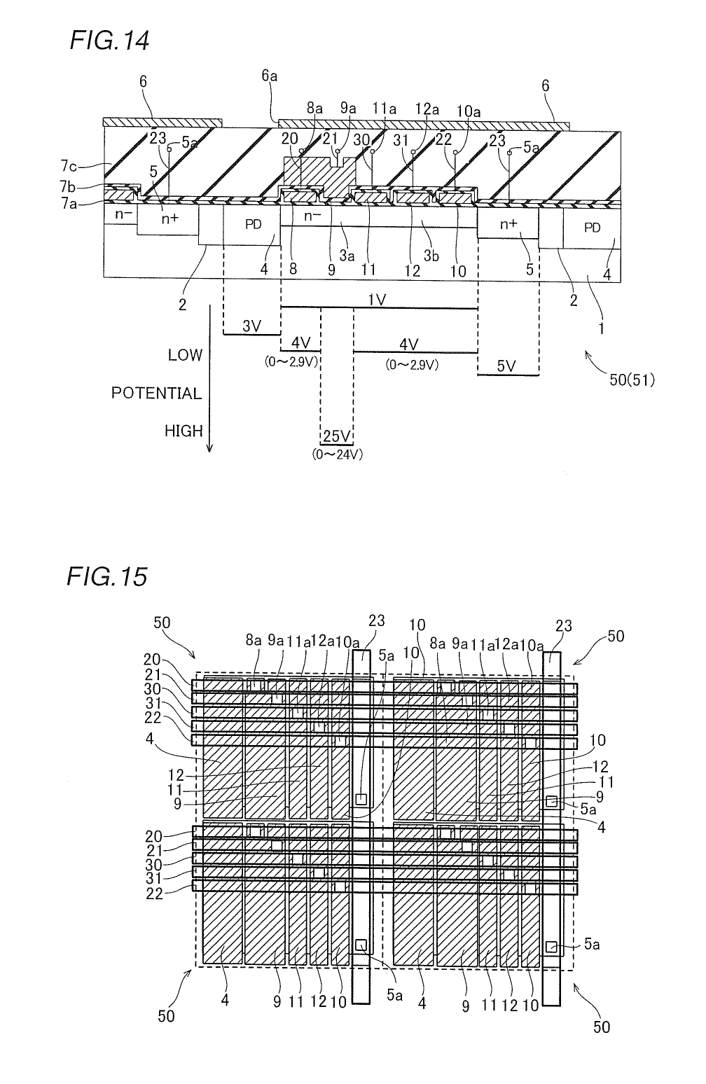

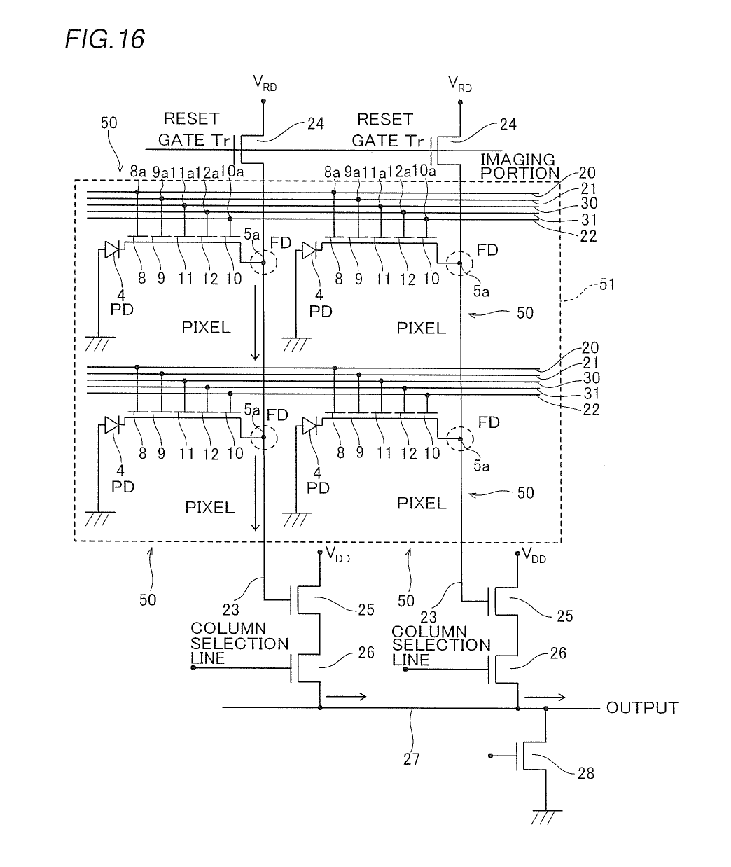

As shown in FIGS. 15 and 16, wiring layers 30 and 31 supplying clock signals φ4 and φ5 for voltage control are electrically connected to the transfer gate electrodes 11 and 12 through contact portions 11a and 12a respectively.

As shown in FIG. 14, when ON-state (high-level) clock signals φ4 and φ5 are supplied to the transfer gate electrodes 11 and 12 through the wiring layers 30 and 31 respectively, voltages of about 2.9 V are applied to the transfer gate electrodes 11 and 12 and portions of the transfer channel 3 located under the transfer gate electrodes 11 and 12 are controlled to potentials of about 4 V.

When OFF-state (low-level) clock signals φ4 and φ5 are supplied to the transfer gate electrodes 11 and 12 through the wiring layers 30 and 31 respectively, voltages of about 0 V are applied to the transfer gate electrodes 11 and 12 and portions of the transfer channel 3 located under the transfer gate electrodes 11 and 12 are controlled to potentials of about 1 V. The remaining structure of the CMOS image sensor according to the second embodiment is similar to that of the CMOS image sensor according to the first embodiment.

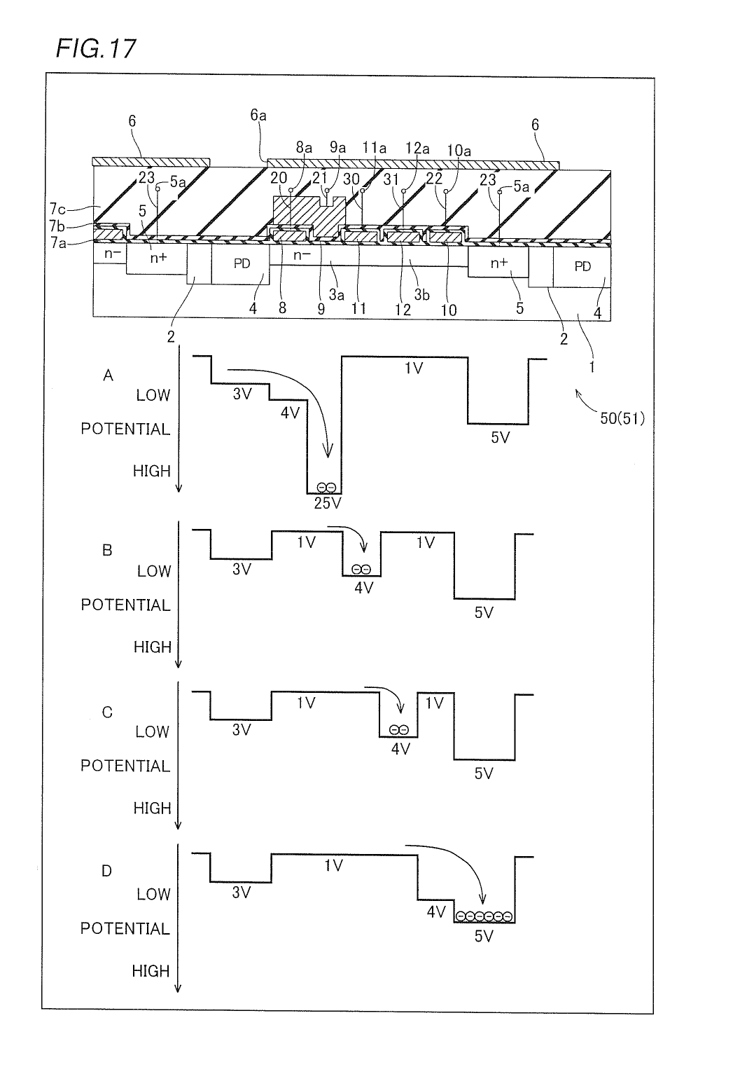

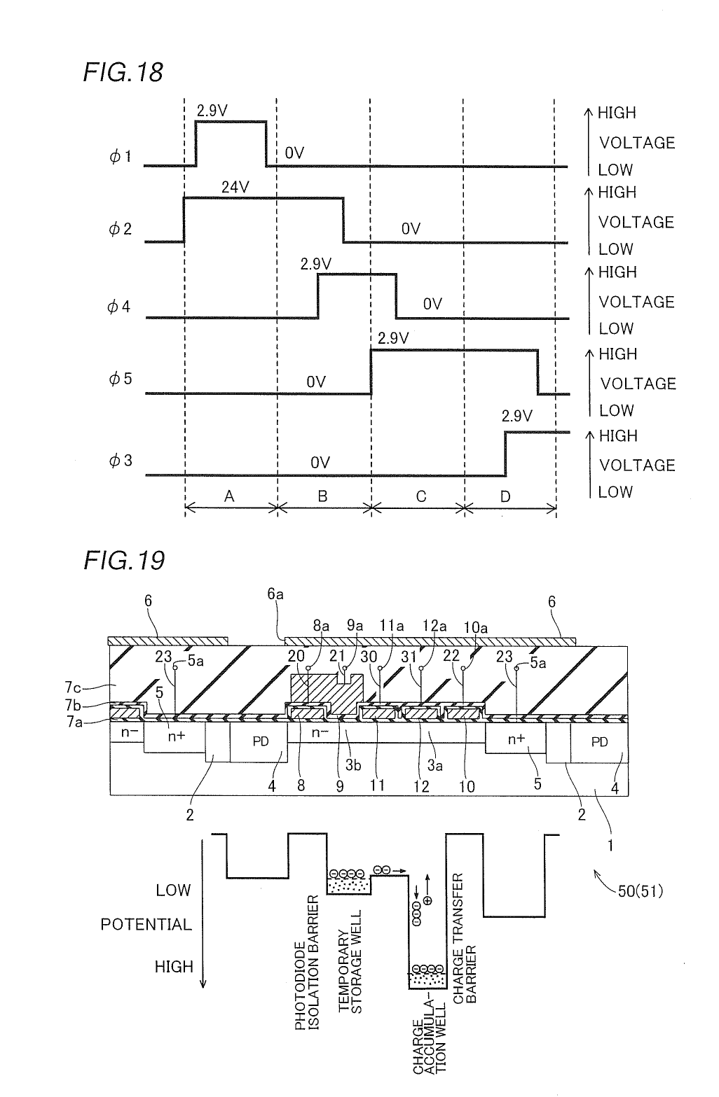

An electron transferring operation of the CMOS image sensor according to the second embodiment will be now described with reference to FIGS. 17 and 18.

In a period A shown in FIGS. 17 and 18, an ON-state voltage (about 24 V) is applied to the multiplier gate electrode 9 and an ON-state voltage (about 2.9 V) is thereafter applied to the transfer gate electrode 8 to transfer electrons generated in the PD portion 4 to the electron multiplying portion 3a under the multiplier gate electrode 9 through the portion of the transfer channel 3 located under the transfer gate electrode 8.

In a period B, an ON-state voltage (about 2.9 V) is applied to the transfer gate electrode 11 and an OFF-state voltage (about 0 V) is thereafter applied to the multiplier gate electrode 9 controlled in an ON state. Thus, electrons are transferred from the portion of the transfer channel 3 located under the multiplier gate electrode 9 (electron multiplying portion 3a) to the portion of the transfer channel 3 located under the transfer gate electrode 11.

In a period C, an ON-state voltage (about 2.9 V) is applied to the transfer gate electrode 12 and an OFF-state voltage (about 0 V) is thereafter applied to the transfer gate electrode 11 controlled in an ON state. Thus, the electrons are transferred from the portion of the transfer channel 3 located under the transfer gate electrode 11 to the portion of the transfer channel 3 located under the transfer gate electrode 12 (electron storage portion 3b).

In a period D, an ON-state voltage (about 2.9 V) is applied to the read gate electrode 10 and an OFF-state voltage (about 0 V) is thereafter applied to the transfer gate electrode 12 controlled in an ON state. Thus, the electrons are transferred from the portion of the transfer channel 3 located under the transfer gate electrode 12 (electron storage portion 3b) to the FD region 5 through the portion of the transfer channel 3 located under the read gate electrode 10.

In the electron multiplying operation of the CMOS image sensor according to the second embodiment, the multiplier gate electrode 9, the transfer gate electrode 11 and the transfer gate electrode 12 are on-off controlled, whereby the electrons are so controlled as to transfer between the portion of the transfer channel 3 located under the multiplier gate electrode 9 (electron multiplying portion 3a) and the portion of the transfer channel 3 located under the transfer gate electrode 12 (electron storage portion 3b) through the portion of the transfer channel 3 located under the transfer gate electrode 11.

According to the second embodiment, the multiplier gate electrode 9 is so formed as to be adjacent to the PD portion 4 through the transfer gate electrode 8 and partially extend on the transfer gate electrode 8 similarly to the aforementioned first embodiment, whereby light obliquely incident from the incident hole 6a of the light shielding film 6 is reflected by the multiplier gate electrode 9 without incidence upon the transfer channel 3. Thus, incidence of light upon the transfer channel 3 can be suppressed and hence noise caused on the CMOS image sensor can be suppressed. The light reflected by the multiplier gate electrode 9 is incident upon the PD portion 4 and hence a light utilization ratio can be increased. Therefore, the photosensitivity of the CMOS image sensor can be improved.

Although the present invention has been described and illustrated in detail, it is clearly understood that the same is by way of illustration and example only and is not to be taken by way of limitation, the spirit and scope of the present invention being limited only by the terms of the appended claims.

For example, while the portions of the transfer channel 3 located under the transfer gate electrode 8 and the read gate electrode 10 respectively are controlled to the potentials of about 4 V when the transfer gate electrode 8 and the read gate electrode 10 are in ON states in each of the aforementioned first and second embodiments, the present invention is not restricted to this but the portions of the transfer channel 3 located under the transfer gate electrode 8 and the read gate electrode 10 respectively may alternatively be controlled to different potentials when the transfer gate electrode 8 and the read gate electrode 10 are in ON states.

While the portions of the transfer channel 3 located under the transfer gate electrodes 8, 11 and 12 and the read gate electrode 10 respectively are controlled to the potentials of about 4 V when the transfer gate electrodes 8, 11 and 12 and the read gate electrode 10 are in ON states in the aforementioned second embodiment, the present invention is not restricted to this but the portions of the transfer channel 3 located under the transfer gate electrodes 8, 11 and 12 and the read gate electrode 10 respectively may alternatively be controlled to different potentials when the transfer gate electrodes 8, 11 and 12 and the read gate electrode 10 are in ON states.

While the transfer channel 3, the PD portion 4 and the FD region 5 are formed on the surface of the p-type silicon substrate 1 in each of the aforementioned first and second embodiments, the present invention is not restricted to this but a p-type well region may alternatively be formed on the surface of an n-type silicon substrate for forming a transfer channel, a PD portion 4 and an FD region 5 on the surface of the p-type well region.

While the electrons are employed as the signal charges in each of the aforementioned first and second embodiments, the present invention is not restricted to this but holes may alternatively be employed as the signal charges by entirely reversing the conductivity type of the substrate impurity and the polarities of the applied voltages.

While the thickness (t1) of the multiplier gate electrode 9 is larger than each of the thicknesses (t2) of the remaining gate electrodes other than the multiplier gate electrode 9 in each of the aforementioned first and second embodiments, the present invention is not restricted to this but each of the thicknesses (t2) of the remaining gate electrodes other than the multiplier gate electrode 9 may be similar to that of the multiplier gate electrode 9.

While the thicknesses (t2) of the remaining gate electrodes other than the multiplier gate electrode are similar to each other in each of the aforementioned first and second embodiments, the present invention is not restricted to this but the thicknesses of the remaining gate electrodes other than the multiplier gate electrode may be different from each other.

While the first insulating film 7a and the second insulating film 7b are formed on the upper surfaces of the channel region 3, the PD portion 4 and the FD region 5 in each of the aforementioned first and second embodiments, the present invention is not restricted to this but only either the first insulating film 7a or the second insulating film 7b may be formed.

While the electron multiplying portion 3a is provided on the portion of the transfer channel 3 located under the multiplier gate electrode 9 and the electron storage portion 3b is provided on the portion of the transfer channel 3 located under the transfer gate electrode 12 in the aforementioned second embodiment, the present invention is not restricted to this but the electron storage portion 3b may be provided on the portion of the transfer channel 3 located under the multiplier gate electrode 9 of the CMOS image sensor of the second embodiment and the electron multiplying portion 3a may be provided on the portion of the transfer channel 3 located under the transfer gate electrode 12 of the CMOS image sensor of the second embodiment as shown in FIG. 19. In this case, the levels of the voltages applied to the multiplier gate electrode 9 and the transfer gate electrode 12 are opposite to the levels of the voltages applied to the multiplier gate electrode 9 and the transfer gate electrode 12 of the CMOS image sensor according to the second embodiment respectively.

While each of the aforementioned first and second embodiments is applied to the passive CMOS image sensor not amplifying a charge signal in each pixel 50 as an exemplary image sensor, the present invention is not restricted to this but is also applicable to an active CMOS image sensor amplifying a charge signal in each pixel. When the present invention is applied to an active CMOS image sensor employed as an exemplary image sensor, each pixel 500 is provided with a reset transistor Tr1 including a reset gate electrode 100, an amplification transistor Tr2 and a pixel selection transistor Tr3 in addition to the transfer gate electrode 8, the multiplier gate electrode 9 and the read gate electrode 10 of the CMOS image sensor according to the aforementioned first embodiment, as shown in FIG. 20. A reset gate line is connected to the reset gate electrode 100 of the reset transistor Tr1 through a contact portion, to supply a reset signal. A drain (reset drain 101) of the reset transistor Tr1 is connected to a power supply potential (VDD) line 500a through another contact portion. The FD region 5 constituting a source of the reset transistor Tr1 and a drain of the read gate electrode 10 and a gate of the amplification transistor Tr2 are connected with each other by a signal line 102. A drain of the pixel selection transistor Tr3 is connected to a source of the amplification transistor Tr2. A row selection line 500b and an output line 500c are connected to a gate and a source of the pixel selection transistor Tr3 respectively.

In an active CMOS image sensor according to a modification of the first embodiment, the number of wires and the number of transistors for decoding can be reduced by the aforementioned circuit structure. Thus, the overall CMOS image sensor can be downsized. In this circuit structure, a read gate electrode 10 is on-off controlled every row, while remaining gate electrodes other than the read gate electrode 10 are simultaneously on-off controlled with respect to the overall pixels 500.

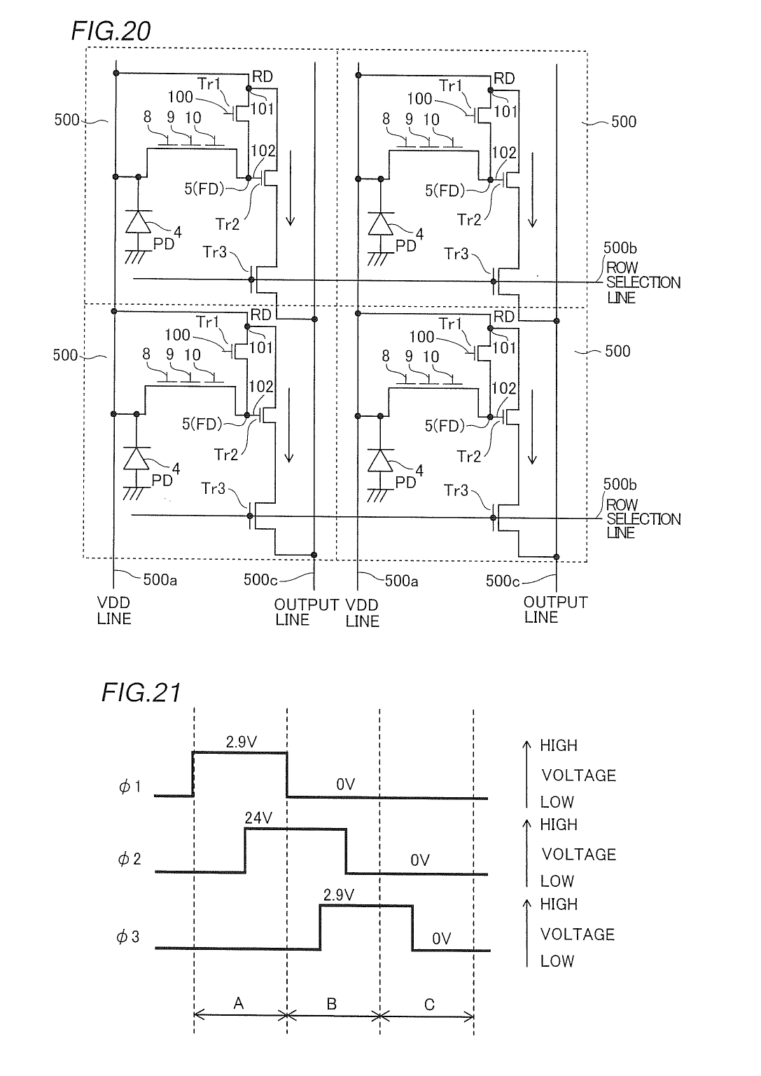

While the ON-state voltage is applied to the portion of the transfer channel 3 located under the multiplier gate electrode 9 (electron multiplying portion 3a) and the ON-state voltage is thereafter applied to the transfer gate electrode 8 to transfer the electrons when the electrons are transferred from the PD portion 4 in each of the aforementioned first and second embodiments, the present invention is not restricted to this but an ON-state voltages may be applied to the electrodes successively from the transfer gate electrode 8 for transferring electrons when the electrons are transferred from the PD portion 4. More specifically, the electrons are transferred from the PD portion 4 to the portion of the transfer channel 3 located under the transfer gate electrode 8 by applying the ON-state voltage to the transfer gate electrode 8 in the period A as shown in FIG. 21. Thereafter an ON-state voltage is applied to the multiplier gate electrode 9 and an OFF-voltage is thereafter applied to the transfer gate electrode 8, to transfer the electrons from the portion of the transfer channel 3 located under the transfer gate electrode 8 to the portion of the transfer channel 3 located under the multiplier gate electrode 9. Thereafter the electrons are controlled to be transferred to the FD region 5 through the portions of the transfer channel 3 located under the read gate electrode 10 through a transfer operation similar to that of the CMOS image sensor according to the first embodiment.

What is claimed is:

1. An image sensor comprising:
a photoelectric conversion portion generating signal charges;
a first electrode for forming an electric field transferring the signal charges generated by said photoelectric conversion portion, formed to be adjacent to said photoelectric conversion portion; and
a second electrode for forming an electric field transferring the signal charges, provided on a side opposite to said photoelectric conversion portion with respect to said first electrode and formed to partially extend on said first electrode.

2. The image sensor according to claim 1, wherein
the thickness of a portion of said second electrode, partially extending on said first electrode is larger than the thickness of said first electrode.

3. The image sensor according to claim 1, wherein
said second electrode is formed to partially extend on said first electrode such that a side end surface of said second electrode on a side opposed to said photoelectric conversion portion extends to a portion close to said photoelectric conversion portion.

4. The image sensor according to claim 3, wherein
said side end surface of said second electrode on the side opposed to said photoelectric conversion portion is aligned substantially along the same line as a side end surface of said first electrode on a side opposed to said photoelectric conversion portion.

5. The image sensor according to claim 4, wherein
light advancing toward said second electrode among the light incident from outside is reflected by said side end surface of said second electrode on the side opposed to said photoelectric conversion portion and guided to said photoelectric conversion portion.

6. The image sensor according to claim 1, further comprising:
an anti-reflection film formed on at least an upper surface of said photoelectric conversion portion and suppressing reflection of light; and
an insulating film formed on said photoelectric conversion portion and said anti-reflection film, wherein
the refractive index of said second electrode is larger than the refractive index of said insulating film.

7. The image sensor according to claim 6, wherein
the refractive index of said anti-reflection film is larger than the refractive index of said insulating film.

8. The image sensor according to claim 6, wherein
said insulating film is made of SiO₂ and said anti-reflection film is made of SiN.

9. The image sensor according to claim 6, wherein
said anti-reflection film is formed also on an upper surface of said first electrode in addition to said upper surface of said photoelectric conversion portion, and
said second electrode is formed to partially extend on said first electrode through said anti-reflection film.

10. The image sensor according to claim 1, further comprising a charge increasing portion for increasing the signal charges.

11. The image sensor according to claim 10, wherein
the signal charges are increased in said charge increasing portion by impact ionization.

12. The image sensor according to claim 11, wherein
said charge increasing portion is provided under said second electrode, and an electric field for increasing the signal charges is formed in said charge increasing portion by applying a prescribed voltage to said second electrode.

13. The image sensor according to claim 10, wherein
a signal charge increasing operation by transfer of the signal charges from said photoelectric conversion portion to said charge increasing portion and a signal charge transferring operation from said charge increasing portion to said photoelectric conversion portion are alternately repeated.

14. The image sensor according to claim 10, further comprising a light shielding film for blocking light incident upon said charge increasing portion, provided on at least said charge increasing portion.

15. The image sensor according to claim 10, further comprising:
a voltage conversion portion for converting the signal charges to a voltage; and
a third electrode forming an electric field transferring the signal charges to said voltage conversion portion, wherein
said photoelectric conversion portion, said first electrode, said second electrode, said third electrode, said charge increasing portion and said voltage conversion portion are included in one pixel.

16. The image sensor according to claim 15, further comprising:
a fourth electrode provided to be adjacent to said second electrode; and
a fifth electrode provided between said fourth electrode and said third electrode.

17. The image sensor according to claim 16, further comprising a charge storage portion for storing the signal charges.

18. The image sensor according to claim 17, wherein
said charge increasing portion is provided under said fifth electrode, and an electric field for increasing the signal charges is formed in said charge increasing portion by applying a prescribed voltage to said fifth electrode and said charge storage portion is provided under said second electrode, and an electric field for storing the signal charges is formed in said charge storage portion by applying a prescribed voltage to said second electrode.

19. The image sensor according to claim 17, wherein
a signal charge increasing operation by transfer of the signal charges from said charge storage portion to said charge increasing portion and a signal charge transferring operation from said charge increasing portion to said charge storage portion are alternately repeated.

20. An image sensor comprising:
a photoelectric conversion portion generating signal charges;
a charge increasing portion for increasing the signal charges; and
a light shielding film for blocking light incident upon said charge increasing portion, provided on at least said charge increasing portion.
